(19) United States
(12) Patent Application Publication
(10) Pub. No.: US 2019/0204494 A1
(43) Pub. Date: Jul. 4, 2019

(54) DISPLAY SCREEN AND DISPLAY DEVICE

(71) Applicant: BOE TECHNOLOGY GROUP CO., LTD., Beijing (CN)

(72) Inventors: Xing ZHAO, Beijing (CN); Lijun SU, Beijing (CN); Zhiguo SHEN, Beijing (CN)

(21) Appl. No.: 16/114,335

(22) Filed: Aug. 28, 2018

(30) Foreign Application Priority Data
Jan. 2, 2018 (CN) 201810002372.6

(51) Int. Cl. F21V 8/00; H05K 1/11; H05K 1/18; G02B 27/22; G09G 3/22

(52) U.S. Cl. CPC G02B 6/004; G02B 6/0053; G09G 3/22; H05K 1/189; G02B 27/22; H05K 1/118

(57) ABSTRACT

A display screen includes a light guide plate having a light incident surface and at least two light emitting surfaces, at least two display panels each correspondingly disposed at a corresponding one of the light emitting surfaces of the light guide plate, and a light source disposed at the light incident surface of the light guide plate.

### CROSS-REFERENCE TO RELATED APPLICATION

This application claims priority to Chinese Patent Application No. 201810002372.6, filed on Jan. 2, 2018, titled “A DISPLAY SCREEN AND DISPLAY DEVICE”, which is incorporated herein by reference in its entirety.

### TECHNICAL FIELD

The present disclosure relates to the field of display technologies, and in particular, to a display screen and a display device.

### BACKGROUND

A display device is a device for displaying a character, a number, a symbol, a picture, or an image formed by combining any two of a character, a number, a symbol and a picture. The display device is for example a flat display device, a curved display device, a 3D (3-Dimensional) display device, a near-eye display device, an AR/VR display device, and the like, in which AR refers to “Augmented Reality” technology, and VR refers to “Virtual Reality” technology.

### SUMMARY

An aspect of the present disclosure provides a display screen, comprising a light guide plate, at least two display panels, and a light source. The light guide plate has a light incident surface and at least two light emitting surfaces. Each display panel is disposed at a corresponding one of the at least two light emitting surfaces of the light guide plate. The light source is disposed at the light incident surface of the light guide plate.

Optionally, at least one of the display panels is connected to the light guide plate.

Optionally, the light guide plate has two light emitting surfaces, and the two light emitting surfaces are disposed opposite to each other.

Optionally, a plurality of scattering netted dots are distributed on each of at least one of the light emitting surfaces of the light guide plate.

Optionally, the plurality of scattering netted dots are distributed on one of the light emitting surfaces of the light guide plate, and a transflective film is disposed between another one of the light emitting surfaces that is not provided with scattering netted dots and a corresponding one of the display panels.

Optionally, a distribution of the plurality of scattering netted dots comprises at least one of: a distribution density of the plurality of scattering netted dots gradually increasing along a direction away from the light incident surface of the light guide plate; or, areas of orthographic projections of the plurality of scattering netted dots on the light emitting surface of the light guide plate gradually increasing along the direction away from the light incident surface of the light guide plate.

Optionally, the light guide plate comprises an extending portion. At least one of the at least two display panels does not overlap with the extending portion, and an end face of the extending portion is the light incident surface of the light guide plate.

Optionally, the display screen further comprises a heat dissipation plate provided with a groove. The light source is disposed at a bottom of the groove, and the extending portion is inserted into the groove of the heat dissipation plate.

Optionally, the display screen further comprises driving circuit boards electrically connected to the display panels in one to one correspondence. At least a portion of each of the driving circuit boards corresponding to at least one of the display panels is attached to the heat dissipation plate.

Optionally, each driving circuit board comprises a printed circuit board and a flexible connecting board. The printed circuit board is attached to the heat dissipation plate, and the flexible connecting board is electrically connected to the printed circuit board and a corresponding one of the display panels.

Optionally, the light guide plate is made of glass, polymethyl methacrylate or polycarbonate.

Optionally, the display screen further comprises a luminance enhancement film disposed between the light guide plate and each of at least one of the display panels.

Optionally, the display screen further comprises a diffusion film disposed between the light guide plate and each of at least one of the display panels.

Optionally, the display screen further comprises a prism film disposed between the light guide plate and each of at least one of the display panels.

Optionally, the display screen further comprises a connecting portion disposed between the light guide plate and each of at least one of the display panels. The connecting portion is configured to connect the light guide plate and a corresponding one of the at least one of the display panels.

Optionally, the connecting portion is an annular spacer, and an inner surface of the annular spacer surrounds a display area of a corresponding display panel. A cross section of the annular spacer in a plane perpendicular to the display panel is made up of two L-shapes. An inner surface of each of the L-shapes is connected to a side surface of a corresponding one of the display panels, and another inner surface of each of the L-shapes is connected to a rear edge of the corresponding one of the display panels. An outer surface of each of the L-shapes parallel to the display panel is connected to the light guide plate.

Another aspect of the present disclosure provides a display device, comprising: the display screen as described in the above technical solution; at least two transparent outer panels; and a supporting portion. The at least two transparent outer panels and the supporting portion are spliced to each other to form a box-like structure, and the display screen is located in the box-like structure. A light exit side of each of the at least two display panels in the display screen corresponds to one of the transparent outer panels.

Optionally, the supporting portion is a support plate.

Optionally, the display device further comprises a signal line. The signal line extends into the box-like structure, and is electrically connected to driving circuit boards respectively corresponding to the display panels in the display screen, and the light source in the display screen.

Optionally, the display device further comprises at least one of: a screen printing structure provided on a portion of each of at least one of the transparent outer panels corresponding to an edge of the display screen; or, a screen printing structure provided on a portion of each of at least one of the transparent outer panels corresponding to an extending portion of the light guide plate in the display screen.

### BRIEF DESCRIPTION OF THE DRAWINGS

In order to describe technical solutions in embodiments of the present disclosure more clearly, the accompanying drawings to be used in the description of embodiments will be introduced briefly. Obviously, the accompanying drawings to be described below are merely some embodiments of the present disclosure, and a person of ordinary skill in the art can obtain other drawings according to those drawings without paying any creative effort.

FIG. 1 is a schematic diagram showing a structure of a display screen according to some embodiments of the present disclosure;

FIG. 2 is a schematic diagram showing a structure of the light guide plate shown in FIG. 1;

FIG. 3 is a schematic diagram showing a distribution of scattering netted dots according to some embodiments of the present disclosure;

FIG. 4 is a schematic diagram showing another distribution of scattering netted dots according to some embodiments of the present disclosure;

FIG. 5 is a schematic diagram showing yet another distribution of scattering netted dots according to some embodiments of the present disclosure;

FIG. 6 is a schematic diagram showing an enlarged structure of the area A shown in FIG. 1;

FIG. 7 is a schematic diagram showing a structure of the annular spacer shown in FIG. 1;

FIG. 8 is a schematic diagram showing a structure of a display device according to some embodiments of the present disclosure; and

FIG. 9 is a right view of the display device shown in FIG. 8.

### DETAILED DESCRIPTION

In order to further illustrate a display screen and a display device provided by some embodiments of the present disclosure, a detailed description will be made below with reference to the accompanying drawings.

In recent years, with the development of display technologies, multi-sided display devices, such as double-sided display devices, have been gradually put forward and come into people's attention. A conventional multi-sided display device typically includes a display screen, which is typically assembled from at least two single-sided display panels. Since each display panel is backlit by a corresponding backlight module, a multi-sided display device needs to adopt at least two backlight modules to achieve display, thereby causing the display screen to be large and cumbersome in size.

Therefore, it is difficult for a double-sided display screen to be embedded between two glass outer panels to be used as window glass because it is large and cumbersome in size.

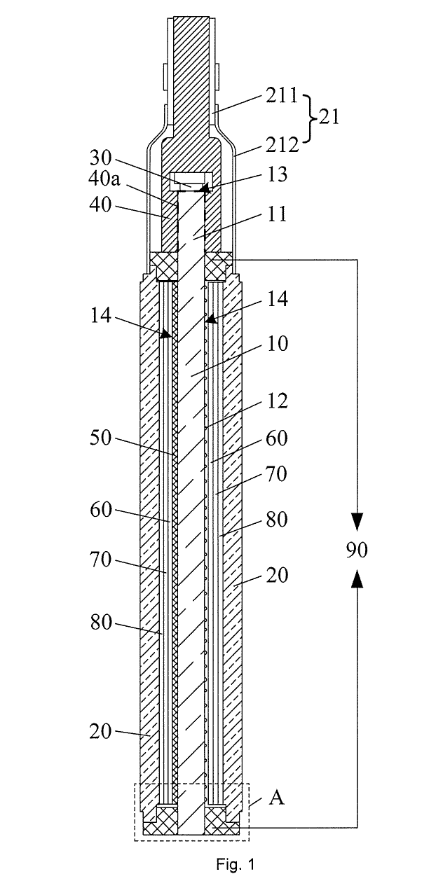

As for the above problem, referring to FIG. 1, some embodiments of the present disclosure provide a display screen. The display screen includes a light guide plate 10, at least two display panels 20, and a light source 30. The light guide plate 10 has a light incident surface 13 and at least two light emitting surfaces 14 that are disposed opposite to each other. Each display panel 20 is disposed at a corresponding one of the at least two light emitting surfaces 14 of the light guide plate 10. The light source 30 is disposed at the light incident surface 13 of the light guide plate 10.

It will be understood that the display screen is a multi-sided display screen, which means that the display screen may realize at least double-sided screen display. For convenience of description, a detailed description about the display screen will be made below by taking a double-sided display screen as an example.

Referring to FIG. 1, in some embodiments, the display screen is a double-sided display screen, which includes a light guide plate 10, a light source 30 and two display panels 20.

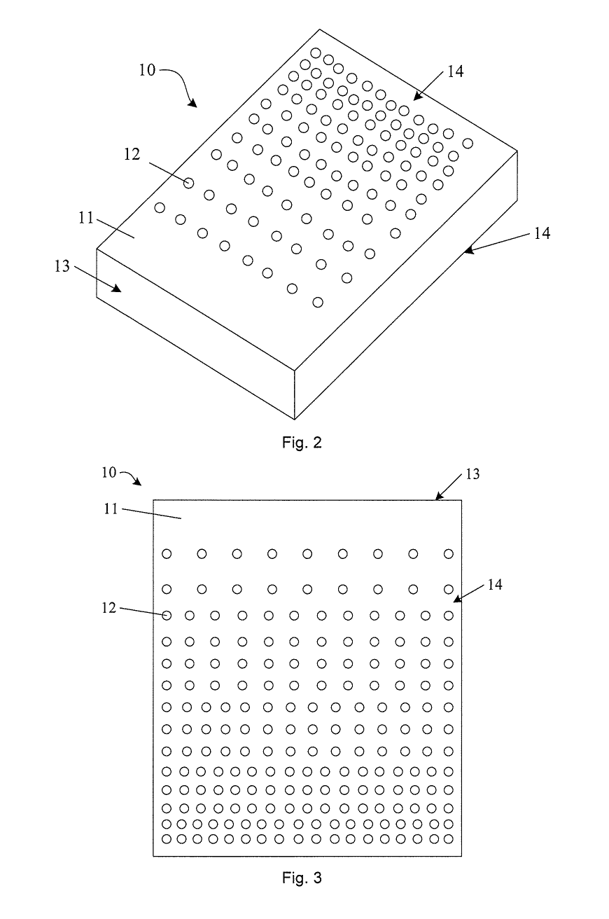

The light guide plate 10 includes a light incident surface 13 and two light emitting surfaces 14. For example, referring to FIG. 2, the light guide plate 10 has a plate-like structure. A front surface of the light guide plate 10 as shown in FIG. 2 (the “front” in “front surface” refers to a surface of the light guide plate 10 close to the reader as shown in FIG. 2) is the light incident surface 13 of the light guide plate 10, and both an upper surface and a lower surface of the light guide plate 10 as shown in FIG. 2 are the light emitting surfaces 14.

The light source 30 (as shown in FIG. 1) is located at the light incident surface 13 of the light guide plate 10. Light emitted by the light source 30 is incident on the light guide plate 10 through the light incident surface 13 of the light guide plate 10, forms planar light sources under the action of the light guide plate 10, and is then emitted from the two light emitting surfaces 14 of the light guide plate 10.

Of the two display panels 20, one display panel 20 is located at one light emitting surface 14 of the light guide plate 10, and another display panel 20 is located at another light emitting surface 14 of the light guide plate 10, so that light, which has been formed to be planar light sources, is emitted from the two light emitting surfaces 14 of the light guide plate 10 for display.

In the case where the display screen displays a picture, the light emitted by the light source 30 is incident on the light guide plate 10 through the light incident surface 13 of the light guide plate 10, and is emitted from the two light emitting surfaces 14 of the light guide plate 10 under the light guiding action of the light guide plate 10. Light emitted from the light emitting surface 14 on a left side of the light guide plate 10 in FIG. 1 serves as a backlight for the display panel 20 on the left side, and light emitted from the light emitting surface 14 on a right side of the light guide plate 10 in FIG. 1 serves as a backlight for the display panel 20 on the right side. The two display panels 20 uses light emitted from the corresponding light emitting surfaces 14 to achieve display, thereby realizing a double-sided display effect of the display screen.

As can be seen from the above analysis, in the display screen provided by the embodiments of the present disclosure, the light guide plate 10 includes the light incident surface 13 and at least two light emitting surfaces 14, each of the at least two display panels 20 is disposed at a corresponding one of the light emitting surfaces 14 of the light guide plate 10, and the light source 30 is disposed at the light incident surface 13 of the light guide plate 10.

In this way, when the display screen works, the light emitted by the light source 30 is incident on the light guide plate 10 through the light incident surface 13 of the light guide plate 10, and is emitted from the two light emitting surfaces 14 of the light guide plate 10 under the light guiding action of the light guide plate 10. The light is then incident on corresponding display panels 20, so as to provide a backlight for the corresponding display panels 20 to achieve display of the display panels 20.

Therefore, the light guide plate 10 is used to provide backlights for at least two display panels 20 to achieve at least two-sided display of the display screen. Compared with the conventional technology, which provides at least two backlight modules, the technical solution provided by the embodiments of the present disclosure may realize the lightweight and thin design of display screens.

For example, referring to FIG. 1, the light guide plate 10 has two light emitting surfaces 14 that are disposed opposite to each other, making it possible for display panels 20 on two oppositely disposed light emitting surfaces 13 of the light guide plate 10 to display images, so that particularly a double-sided display screen may be embedded between two outer glass panels for use as window glass. Referring to FIGS. 1-5, in some embodiments of the present disclosure, a plurality of scattering netted dots 12 are distributed on at least one of the light emitting surfaces 14 of the light guide plate 10.

In the case where the display screen is a double-sided display screen and referring to FIG. 1, the light guide plate 10 includes the light incident surface 13 and two light emitting surfaces 14 that are disposed opposite to each other, in some embodiments, a plurality of scattering netted dots 12 are distributed on one of the light emitting surfaces 14. For example, in FIG. 1, a plurality of scattering netted dots 12 are distributed on the light emitting surface 14 on the right side of the light guide plate 10, so as to scatter the light incident on the light emitting surface 14 of the light guide plate 10 through the light incident surface 13 to improve the uniformity of light emitted from the light emitting surface 14 of the light guide plate 10, that is, to improve the uniformity of the backlight provided for the display panel 20 by the light guide plate 10.

With continued reference to FIG. 1, in some embodiments of the present disclosure, a plurality of scattering netted dots 12 are distributed on one of the light emitting surfaces 14 of the light guide plate 10, and a transflective film 50 is disposed between another light emitting surface 14 of the light guide plate 10 that is not provided with scattering netted dots 12 and a corresponding one of the display panels 20.

For example, in the case where the display screen is a double-sided display screen and referring to FIG. 1, the light guide plate 10 includes the light incident surface 13 and two light emitting surfaces 14 that are disposed opposite to each other, a plurality of scattering netted dots 12 are distributed on one light emitting surface 14, while another light emitting surface 14 is not provided with scattering netted dots 12.

For example, in FIG. 1, a plurality of scattering netted dots 12 are distributed on the light emitting surface 14 on the right side of the light guide plate 10, while the light emitting surface 14 on the left side of the light guide plate 10 is not provided with scattering netted dots. In this case, as shown in FIG. 1, a transflective film 50 is disposed between the light emitting surface 14 on the left side of light guide plate 10 and the display panel 20 on the left side, so as to reflect a portion of the light emitted from the light emitting surface 14 that is not provided with scattering netted dots 12 to the light emitting surface 14 that is provided with the scattering netted dots 12. The reflected light is then emitted from the light emitting surface 14 that is provided with the scattering netted dots 12, thereby increasing the intensity of light emitted from the light emitting surface 14 that is provided with the scattering netted dots 12.

Furthermore, in some embodiments, a luminance on both sides of the double-sided display screen and a difference in luminance between the two sides of the double-sided display screen are both adjusted by adjusting a ratio of light transmitted by the transflective film 50 to light reflected by the transflective film 50, so as to make the double-sided display screen adapt to different environments on both sides.

For example, in the case where the double-sided display is embedded between outer glass panels for use as window glass, there is usually a difference between the luminance inside the vehicle and the luminance outside the vehicle. In order to improve the display effect on both sides of the double-sided display screen, the double-sided display screen will require different levels of luminance on the two sides.

In this way, by adjusting the ratio of light transmitted by the transflective film 50 to light reflected by the transflective film 50, the luminance on both sides of the double-sided display screen and the difference in luminance between the two sides of the double-sided display screen may be adjusted. As a result, when the double-sided display screen is embedded between outer glass panels for use as the window glass, the double-sided display screen may adapt to different environments inside and outside the vehicle by making the side of the screen provided with scattering netted dots 12 face the inside of the vehicle and the side of the screen provided with the transflective film 50 face the outside of the vehicle.

In the above embodiments, at least one of the light emitting surfaces 14 of the light guide plate 10 is provided with a plurality of scattering netted dots 12, and there are a plurality of ways in which the plurality of scattering netted dots 12 are distributed on the corresponding light emitting surface 14.

In some embodiments, referring to FIG. 3, a distribution density of the plurality of scattering netted dots 12 gradually increases along a direction away from the light incident surface 13 of the light guide plate 10.

For example, assuming that in FIG. 3, an upper surface of the light guide plate 10 is the light incident surface 13 of the light guide plate 10, then the distribution density of the scattering netted dots 12 gradually increases along a direction from top to bottom, that is, the scattering netted dots 12 are distributed more and more intensively along the direction from top to bottom, so as to enhance the scattering effect of light farther away from the light incident surface 13 and increase the uniformity of the backlight provided by the light guide plate 10.

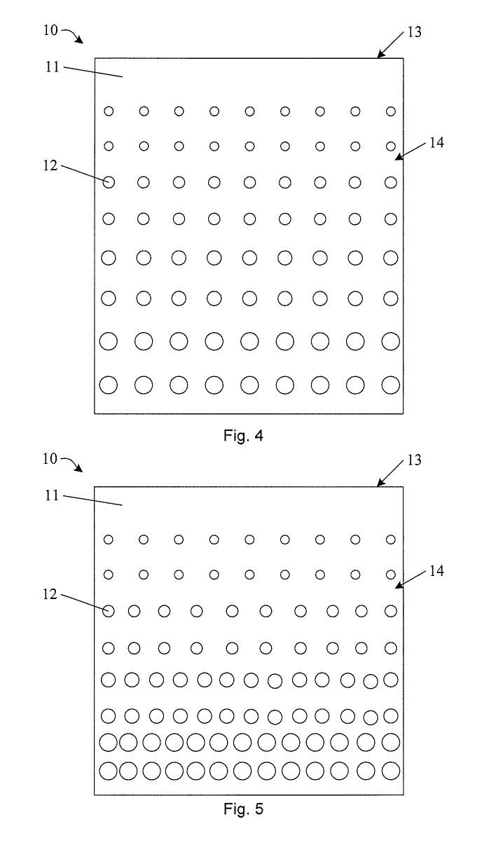

In some other embodiments, referring to FIG. 4, areas of orthographic projections of the scattering netted dots 12 on the light emitting surface 14 of the light guide plate 10 gradually increase along a direction away from the light incident surface 13 of the light guide plate 10.

For example, assuming that in FIG. 4, the upper surface of the light guide plate 10 is the light incident surface 13 of the light guide plate 10, then the areas of the orthographic projections of the scattering netted dots 12 on the light emitting surface 14 of the light guide plate 10 gradually increase along the direction from top to bottom, so as to enhance the scattering effect of light farther away from the light incident surface 13 and increase the uniformity of the backlight provided by the light guide plate 10.

In some other embodiments, referring to FIG. 5, the distribution density of the scattering netted dots 12 gradually increases, and the areas of the orthographic projections of the scattering netted dots 12 on the light emitting surface 14 of the light guide plate 10 gradually increase along a direction away from the light incident surface 13 of the light guide plate 10. That is, both the distribution density of the scattering netted dots 12 and the areas of the orthographic projections of the scattering netted dots 12 on the light emitting surface 14 of the light guide plate 10 change simultaneously along a direction away from the light incident surface 13 of the light guide plate 10, so as to enhance the scattering effect of light farther away from the light incident surface 13 and increase the uniformity of the backlight provided by the light guide plate 10.

With continued reference to FIG. 1, in some embodiments of the present disclosure, the light guide plate 10 includes an extending portion 11. At least one of the at least two display panels 20 does not overlap with the extending portion 11, and an end face of the extending portion 11 is the light incident surface 13 of the light guide plate 10.

That is, in the case where the display panels 20 are of the same size, the light guide plate 10 provided by the embodiments of the present disclosure is longer than a conventional light guide plate. The extending portion 11 does not overlap with the at least one of the display panels 20 (i.e., no overlap in a thickness direction of the display panel 20), so that the double-sided display screen may be made very thin.

With continued reference to FIG. 1, in some embodiments of the present disclosure, the display screen further includes a heat dissipation plate 40 provided with a groove 40a. The light source 30 is disposed at a bottom of the groove 40a, and the extending portion 11 is inserted into the groove of the heat dissipation plate 40.

In some embodiments, with continued reference to FIGS. 1 and 2, in the case where the display screen is a double-sided display screen in which the light guide plate 10 includes a light incident surface 13 and two light emitting surfaces 14 that are disposed opposite to each other, and two display panels 20 are disposed at corresponding light emitting surfaces 14 respectively, the light guide plate 10 includes a body portion located between the two display panels 20 and an extending portion 11 protruding from the two display panels 20. The end face of the extending portion 11 is the light incident surface 13 of the light guide plate 10, that is, an upper surface of the extending portion 11 in FIG. 1 is the light incident surface 13 of the light guide plate 10. In addition, the display screen further includes a heat dissipation plate 40, and the heat dissipation plate 40 is provided with a groove. The light source 30 is disposed at the bottom of the groove, and the extending portion 11 of the light guide plate 10 is inserted into the groove of the heat dissipation plate 40.

With continued reference to FIG. 1, in some embodiments, the display screen further includes driving circuit boards 21 electrically connected to the display panels 20 in one to one correspondence. At least a portion of the driving circuit board(s) 21 corresponding to at least one of the display panels 20 is attached to the heat dissipation plate 40.

For example, the driving circuit board 21 of the display panel 20 includes a printed circuit board 211 and a flexible connecting board 212. The printed circuit board 211 is attached to the heat dissipation plate 40, and the flexible connecting board 212 is electrically connected to the printed circuit board 211 and the display panel 20.

The flexible connecting board 212 is bound to a binding area on a base substrate of the display panel 20. The printed circuit board 211 is electrically connected to the flexible connecting board 212. The printed circuit board 211 is laid on the heat dissipation plate 40 and is connected to the heat dissipation plate 40.

For example, a connection of the printed circuit board 211 and the heat dissipation plate 40 is achieved by means of adhesive bonding. Compared with the technical solution of bending the driving circuit board 21 of the display panel 20 to the back side of the display panel 20 in the related art, this design makes it even easier to realize the lightweight and thin design of display screens. In particular, for a double-sided display screen provided with two display panels 20 on both sides, its thickness may be reduced, so that the double-sided display screen may be lighter and thinner, and may be embedded between two outer glass panels for use as window glass.

In addition, in the related art, the light incident surface 13 of the light guide plate 10 abuts against the display panel 20. However, in the embodiments of the present disclosure, the light guide plate 10 includes the extending portion 11, and the end face of the extending portion 11 is the light incident surface 13 of the light guide plate 10. That is, the light incident surface 13 of the light guide plate 10 is far away from the display panel 20, and the light source 30 is disposed at the light incident surface 13 of the light guide plate 10. Therefore, the light source 30 is also far away from the display panel 20, and the amount of heat transferred to the display panel 20 during operation of the light source 30 may be reduced.

Moreover, the light source 30 is disposed in the groove of the heat dissipation plate 40, and at least a portion of the driving circuit board 21 of the display panel 20 is attached to the heat dissipation plate 40, so that the heat dissipation plate 40 may be used for dissipating heat generated during operations of the light source 30 and the driving circuit board 21 of the display panel 20.

Furthermore, the extending portion 11 is inserted into the groove of the heat dissipation plate 40, and the heat dissipation plate 40 is usually made of metal such as copper or aluminum that has a good heat dissipation effect. Since these metals can block light, the problem of light leakage at the area of the extending portion 11 may be avoided.

In the above embodiments, the light guide plate 10 is made of various kinds of materials. For example, the light guide plate 10 is made of glass, polymethyl methacrylate, or polycarbonate.

In particular, in the case where the light guide plate 10 is made of glass, the light guide plate 10 and the base substrate in the display panel 20 expand and contract to a similar extent when subjected to changes in temperature, thereby preventing the backlight provided by the light guide plate 10 for the display panel 20 from being mismatched with the display panel 20 due to thermal expansion and contraction. Therefore, the above display screen provided by the embodiments of the present disclosure may be applied to an environment with a large temperature difference.

With continued reference to FIG. 1, in some embodiments of the present disclosure, the display screen further includes a luminance enhancement film 80 disposed between the light guide plate 10 and each of at least one of the display panels 20.

FIG. 1 is a schematic diagram taking an example in which luminance enhancement films 80 are disposed between the light guide plate 10 and both of the two display panels 20 respectively.

With the use of the luminance enhancement films 80, the luminance of the backlight provided by the light guide plate 10 for the display panels 20 may be improved. As a result, the quality of the backlight provided by the light guide plate 10 for the display panels 20 may be improved, and the display quality of the display screen may be enhanced.

With continued reference to FIG. 1, in some embodiments of the present disclosure, the display screen further includes a diffusion film 60 disposed between the light guide plate 10 and each of at least one of the display panels 20.

FIG. 1 is a schematic diagram taking an example in which diffusion films 60 are disposed between the light guide plate 10 and both of the two display panels 20, respectively.

With the use of the diffusion films 60, the uniformity of the backlight provided by the light guide plate 10 for the display panels 20 may be improved, and the display quality of the display screen may be enhanced.

With continued reference to FIG. 1, in some embodiments of the present disclosure, the display screen further includes a prism film 70 disposed between the light guide plate 10 and each of at least one of the display panels 20.

FIG. 1 is a schematic diagram taking an example in which prism films 70 are disposed between the light guide plate 10 and both of the two display panels 20, respectively.

With the use of the prism films 70, the uniformity of the backlight provided by the light guide plate 10 for the display panels 20 may be improved, and the display quality of the display screen may be enhanced.

In the case where the diffusion film 60, the prism film 70 and the luminance enhancement film 80 are disposed between the light guide plate 10 and any one of the display panels 20 at the same time, the order of the diffusion film 60, the prism film 70 and the luminance enhancement film 80 is for example as follows. The diffusion film 60, the prism film 70 and the luminance enhancement film 80 are arranged in order in a direction from the light guide plate 10 to the display panel 20.

Moreover, in the case where the transflective film 50, the diffusion film 60, the prism film 70 and the luminance enhancement film 80 are disposed between the light guide plate 10 and the display panel 20 at the same time, the order of the transflective film 50, the diffusion film 60, the prism film 70 and the luminance enhancement film 80 is for example as follows. The transflective film 50, the diffusion film 60, the prism film 70 and the luminance enhancement film 80 are arranged in order in a direction from the light guide plate 10 to the display panel 20.

In the above embodiments, the display panel 20 is connected to the light guide plate 10. There are a variety of ways in which the display panel 20 and the light guide plate 10 are connected. For example, the display panel 20 is adhesively bonded to the light guide plate 10.

With continued reference to FIG. 1, in some embodiments, at least one of the display panels 20 is connected to the light guide plate 10, so that the display screen has a relatively firm structure.

In some embodiments, as shown in FIGS. 1, 6 and 7, the display screen further includes a connecting portion 90 disposed between the light guide plate 10 and each of at least one of the display panels 20, and the connecting portion 90 is configured to connect the light guide plate 10 and a corresponding one of the display panels 20.

In some embodiments, the display screen includes two display panels 20, and two connecting portions 90 are disposed between the light guide plate 10 and the display panels 20 respectively, that is, each of the light emitting surfaces 14 of the light guide plate 10 is provided with a single connecting portion 90.

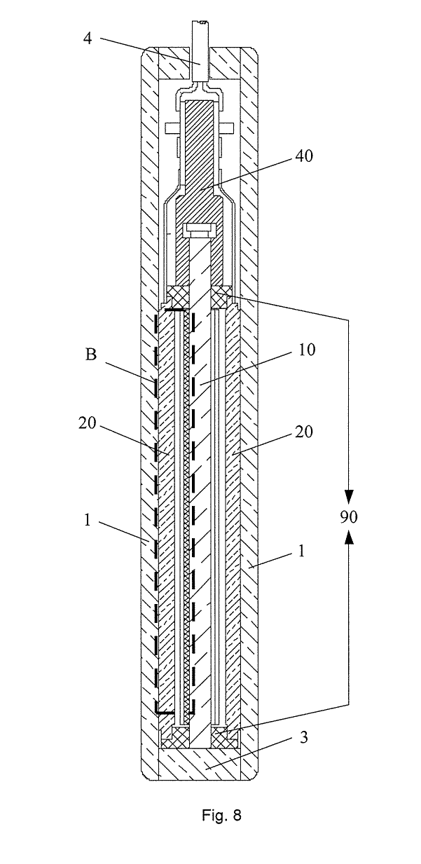

For example, the connecting portion 90 is an annular spacer 90. An inner ring of the annular spacer 90 surrounds a display area B of the corresponding display panel 20 (as shown in FIG. 8). A cross section of the annular spacer 90 in a plane perpendicular to the display panel 20 is made up of two L-shapes. An inner surface of each of the L-shapes is connected to a side surface of the corresponding display panel 20, another inner surface of each of the L-shapes is connected to a rear edge of the corresponding display panel 20, and an outer surface of each of the L-shapes parallel to the display panel 20 is connected to the light guide plate 10.

Referring to FIGS. 1, 6 and 7, in a plane perpendicular to the display panel 20 (i.e., a plane parallel to the paper), the cross section of the annular spacer 90 is made up of two separate L-shapes one on top and one on the bottom (here “top” and “bottom” are based on the top and bottom directions of the paper). Each of the L-shapes includes a first inner surface 91, a second inner surface 92, a first outer surface 93 (since the first outer surface 93 is located at the bottom in FIG. 7, it is not shown in FIG. 7), a second outer surface 94, a first end surface 95 and a second end surface 96.

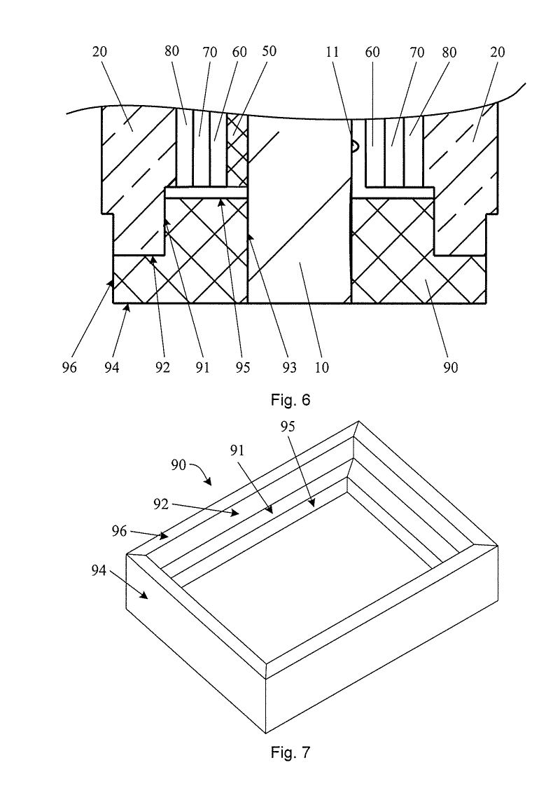

In FIG. 6 in which one of the two separate L-shapes on the bottom is shown, the first end surface 95 of the L-shape corresponds to the inner ring of the annular spacer 90, and surrounds the display area of the corresponding display panel 20. The first inner surface 91 of the L-shape is connected to the rear edge of the corresponding display panel 20, for example, via double-sided tape. The second inner surface 92 of the L-shape is connected to the side surface of the corresponding display panel 20, for example, via double-sided tape. The first outer surface 93 of the L-shape is parallel to the first inner surface 91 of the L-shape, therefore the first outer surface 93 of the L-shape is also parallel to the corresponding display panel 20, and the first outer surface 93 of the L-shape is connected to the light guide plate 10, for example, via double-sided tape.

In this way, the light guide plate 10 is connected to the display panel 20 through the annular spacer 90, and the inner ring of the annular spacer 90 surrounds the display area of the corresponding display panel 20. As a result, the space between the display panel 20 and the light guide plate 10 is enclosed, thereby preventing dust, foreign matter and the like from entering the space between the display panel 20 and the light guide plate 10.

In particular, the cross section of the annular spacer 90 is made up of two L-shapes, an inner surface of the annular spacer 90 is connected to the side surface of the corresponding display panel 20, and another inner surface is connected to the rear edge of the corresponding display panel 20, therefore the inner surfaces of the annular spacer 90 surround the rear edge and the side surface of the corresponding display panel 20, thereby further preventing dust, foreign matter and the like from entering the space between the display panel 20 and the light guide plate 10.

In addition, since the annular spacer 90 is disposed between the light guide plate 10 and each of at least one of the display panels 20, there is a certain space between the display panel 20 and the light guide plate 10, making it possible for optical films to be disposed between the display panel 20 and the light guide plate 10. The optical films include, for example, a transflective film 50, a diffusion film 60, a prism film 70, and a luminance enhancement film 80.

Moreover, the annular spacer 90 may also provide support for and limit the positions of the optical films, such as the transflective film 50, the diffusion film 60, the prism film 70 and the luminance enhancement film 80.

With continued reference to FIG. 8, some embodiments of the present disclosure provide a display device. The display device includes the display screen provided by the above embodiments, at least two transparent outer panels 1, and a supporting portion 3. The at least two transparent outer panels 1 and the supporting portion 3 are spliced to each other to form a box-like structure, and the display screen is located in the box-like structure. A light exit side of each of the display panels 20 in the display screen faces one of the transparent outer panels 1.

The shape of the supporting portion 3 includes, but is not limited to, a plate shape. Since the two transparent outer plates 1 are both of a plate shape, in order to facilitate the splicing between the supporting portion 3 and the two plate-shaped transparent outer plates 1, the supporting portion 3 is a support plate 3.

For example, taking an example in which the display screen is a double-sided display screen, the display device is a double-sided display device, which includes a double-sided display screen, two transparent outer panels 1 and a support plate 3.

The two transparent outer panels 1 are both for example outer glass panels, and the support plate 3 is also for example a glass support plate. The two transparent outer panels 1 are disposed opposite and parallel to each other, and the double-sided display screen is located between the two transparent outer panels 1. The support plate 3 is located between the two transparent outer panels 1 in a space other than the double-sided display screen to support the double-sided display screen.

The double-sided display device is for example used as window glass for a vehicle or a shop.

The above display device has the same advantages as the above display screen relative to the conventional art, and details are not described herein again.

With continued reference to FIG. 8, in some embodiments, the display device further includes a signal line 4. The signal line 4 extends into the box-like structure, and is electrically connected to driving circuit boards 21 respectively corresponding to the display panels 20 in the display screen and the light source 30 in the display screen, so as to provide power for the light source 30 of the display screen to emit light, and provide power and display signals for the display panels 20 to display content. The signal line 4 is for example a signal cable.

Therefore, by using the signal line 4 to provide power for the light source 30 to emit light and provide power and display signals for the display panels 20 to display content, the number of data lines may be reduced.

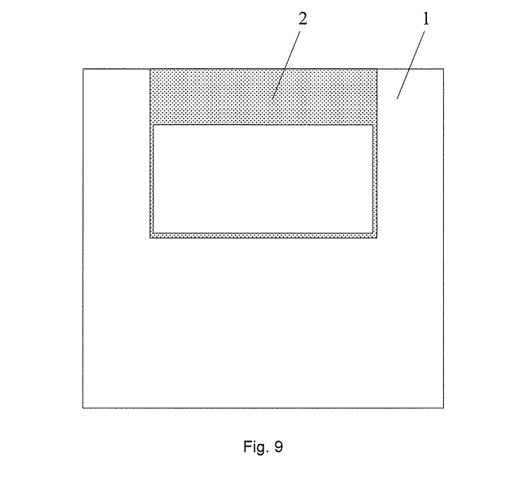

Referring to FIG. 9, in some embodiments, a portion of each of at least one of the transparent outer panels 1 corresponding to an edge of the display screen is provided with a screen printing structure 2. In some other embodiments, a portion of each of at least one of the transparent outer panels 1 corresponding to the extending portion 11 of the light guide panel 10 in the display screen is provided with a screen printing structure 2. In some other embodiments, a portion of each of at least one of the transparent outer panels 1 corresponding to an edge of the display screen, and a portion of each of at least one of the transparent outer panels 1 corresponding to the extending portion 11 of the light guide panel 10 in the display screen are both provided with a screen printing structure 2

With this design, the edge of the display screen may be blocked by the screen printing structure 2 on each of at least one of the transparent outer panels 1, and/or, the extending portion 11 of the light guide panel 10 in the display screen may be blocked by the screen printing structure 2 on each of at least one of the transparent outer panels 1, so that people may be prevented from seeing the edge of the display screen and/or the structure of the heat dissipation plate 40 in the display screen from an outer side of the transparent outer panel 1 relative to the display screen, and the appearance of the display device may be improved.

In some embodiments, the display screen is a double-sided display screen, and the display device is a double-sided display device.

In the case where the double-sided display device is used as the window glass for the vehicle, and the double-sided display device is mounted on a window frame of the vehicle, in some embodiments, the portion of the double-sided display device corresponding to the extending portion 11 of the light guide plate 10 is hidden in the window frame. In this case, the area of the transparent outer panel 1 corresponding to the extending portion 11 is not provided with the screen printing structure 2.

In the case where the double-sided display device is mounted on the window frame of the vehicle, in some embodiments, the portion of the double-sided display device corresponding to the extending portion 11 of the light guide plate 10 is hidden in the window frame. In this case, the area of the transparent outer panel 1 corresponding to the extending portion 11 is not provided with the screen printing structure 2, either.

In the above description of the implementation manners, specific features, structures, materials or characteristics may be combined in any suitable manner in any one or more embodiments or examples.

The foregoing descriptions are merely exemplary implementation manners of the present disclosure, but the protection scope of the present disclosure is not limited thereto, and the changes or replacements that any person skilled in the art can easily think of in the technical scope disclosed by the present disclosure should be within the protection scope of the present disclosure. Therefore, the protection scope of the present disclosure shall be subject to the protection scope of the claims.

What is claimed is:

1. A display screen, comprising:
a light guide plate having a light incident surface and at least two light emitting surfaces;
at least two display panels, each display panel being disposed at a corresponding one of the at least two light emitting surfaces of the light guide plate; and
a light source disposed at the light incident surface of the light guide plate.

2. The display screen according to claim 1, wherein at least one of the display panels is connected to the light guide plate.

3. The display screen according to claim 2, wherein the light guide plate has two light emitting surfaces, and the two light emitting surfaces are disposed opposite to each other.

4. The display screen according to claim 2, wherein a plurality of scattering netted dots are distributed on each of at least one of the light emitting surfaces of the light guide plate.

5. The display screen according to claim 4, wherein the plurality of scattering netted dots are distributed on one of the light emitting surfaces of the light guide plate; and
a transflective film is disposed between another one of the light emitting surfaces that is not provided with scattering netted dots and a corresponding one of the display panels.

6. The display screen according to claim 4, wherein a distribution of the plurality of scattering netted dots comprises at least one of:
a distribution density of the plurality of scattering netted dots gradually increasing along a direction away from the light incident surface of the light guide plate, or
areas of orthographic projections of the plurality of scattering netted dots on a corresponding one of the light emitting surfaces of the light guide plate gradually increasing along the direction away from the light incident surface of the light guide plate.

7. The display screen according to claim 2, wherein the light guide plate comprises an extending portion, at least one of the at least two display panels does not overlap with the extending portion, and an end face of the extending portion is the light incident surface of the light guide plate.

8. The display screen according to claim 7, further comprising:
a heat dissipation plate provided with a groove, wherein
the light source is disposed at a bottom of the groove, and the extending portion is inserted into the groove of the heat dissipation plate.

9. The display screen according to claim 8, further comprising:
driving circuit boards electrically connected to the at least two display panels in one to one correspondence, wherein
at least a portion of each of the driving circuit boards corresponding to at least one of the display panels is attached to the heat dissipation plate.

10. The display screen according to claim 9, wherein each driving circuit board comprises a printed circuit board and a flexible connecting board;
the printed circuit board is attached to the heat dissipation plate, and the flexible connecting board is electrically connected to the printed circuit board and a corresponding one of the display panels.

11. The display screen according to claim 2, wherein the light guide plate is made of glass, polymethyl methacrylate or polycarbonate.

12. The display screen according to claim 2, further comprising:
a luminance enhancement film disposed between the light guide plate and each of at least one of the display panels.

13. The display screen according to claim 2, further comprising:
a diffusion film disposed between the light guide plate and each of at least one of the display panels.

14. The display screen according to claim 2, further comprising:
a prism film disposed between the light guide plate and each of at least one of the display panels.

15. The display screen according to claim 7, further comprising:
a connecting portion disposed between the light guide plate and each of at least one of the display panels, wherein the connecting portion is configured to connect the light guide plate and a corresponding one of the at least one of the display panels.

16. The display screen according to claim 15, wherein
the connecting portion is an annular spacer;
an inner surface of the annular spacer surrounds a display area of a corresponding one of the display panels;
a cross section of the annular spacer in a plane perpendicular to the display panel is made up of two L-shapes; an inner surface of each of the L-shapes is connected to a side surface of the corresponding one of the display panels, and another inner surface of each of the L-shapes is connected to a rear edge of the corresponding one of the display panels; and an outer surface of each of the L-shapes parallel to the display panel is connected to the light guide plate.

17. A display device, comprising:
the display screen according to claim 1;
at least two transparent outer panels; and
a supporting portion, wherein,
the at least two transparent outer panels and the supporting portion are spliced to each other to form a box-like structure, the display screen is located in the box-like structure, and a light exit side of each of at least two display panels in the display screen corresponds to one of the transparent outer panels.

18. The display device according to claim 17, wherein the supporting portion is a support plate.

19. The display device according to claim 18, further comprising:
a signal line, wherein the signal line extends into the box-like structure, and is electrically connected to driving circuit boards corresponding to the display panels in the display screen, and the light source in the display screen.

20. The display device according to claim 18, further comprising at least one of:
a screen printing structure provided on a portion of each of at least one of the transparent outer panels corresponding to an edge of the display screen; or
a screen printing structure provided on a portion of each of at least one of the transparent outer panels corresponding to an extending portion of the light guide plate in the display screen.
